(19) United States
(12) Patent Application Publication
(10) Pub. No.: US 2019/0078201 A1
(43) Pub. Date: Mar. 14, 2019

(54) HEM FLANGE PLASMA TREATMENT PROCESS

(71) Applicant: Ford Global Technologies, LLC, Dearborn, MI (US)

(72) Inventors: Larry P. Haack, Ann Arbor, MI (US); Ann Marie Straccia, Southgate, MI (US); Kenneth Edward Nietering, Dearborn, MI (US)

(21) Appl. No.: 16/190,885

(22) Filed: Nov. 14, 2018

Related U.S. Application Data
(62) Division of application No. 14/794,379, filed on Jul. 8, 2015, now abandoned.

(51) Int. Cl. C23C 16/40; C23C 16/455; B05D 5/06; B05D 1/00; C23C 16/513; B05D 7/00

(52) U.S. Cl. CPC C23C 16/401; C23C 16/45595; B05D 5/068; B05D 1/62; Y10T 428/31598; B05D 2518/10; B05D 2420/02; B05D 7/58; B05D 2420/01; C23C 16/513

(57) ABSTRACT

A hem flange treatment method. The method includes air plasma direct spraying a hem flange at an outer edge of an outer panel thereof with a plasma polymer direct spray to cover the outer edge with a protective direct spray region. The method further includes air plasma overspraying an inner cut edge of an inner panel of the hem flange with a plasma polymer overspray to form a protective overspray region that covers the inner cut edge.

### CROSS-REFERENCE TO RELATED APPLICATIONS

This application is a divisional of U.S. application Ser. No. 14/794,379 filed Jul. 8, 2015, now abandoned, which is a divisional of U.S. application Ser. No. 13/659,359 filed Oct. 24, 2012, the disclosures of which are hereby incorporated in their entirety by reference herein.

### TECHNICAL FIELD

The present invention relates to process for forming plasma treated hem flanges.

### BACKGROUND

Certain metallic parts and particularly those used in the manufacture of vehicles are often subject to corrosion if exposed to the environment. Non-limiting examples of these metallic parts include cut edges of door frames and hem flanges of support panels. The general feature that makes these metallic parts susceptible to corrosion is the inclusion of cut metal upon which the intended corrosion protection is breached, allowing for contact with the environment. Moreover, areas of these metallic parts may be hidden or cannot be accessed by direct line of sight. Geometry constraints can prevent effective coverage of spray coatings and even electro-deposition coatings (electro-coat) into tight and hidden areas where corrosion may subsequently develop. Any corrosion that is able to initiate in these areas is then free to propagate laterally, undercutting protected areas. If unchecked, areas of exposed metal may eventually corrode, leading to appearance issues and customer dissatisfaction.

### SUMMARY

In a first embodiment, a hem flange treatment method is disclosed. The method includes air plasma direct spraying a hem flange at an outer edge of an outer panel thereof with a plasma polymer direct spray to cover the outer edge with a protective direct spray region. The method further includes air plasma overspraying a cut edge of an inner panel of the hem flange with a plasma polymer overspray to form a protective overspray region that covers the inner cut edge.

In a second embodiment, a hem flange treatment method is disclosed. The method includes electrocoating a hem flange having inner and outer panels, each including inner surfaces, to form inner panel surface coated and exposed regions. The method further includes spraying the hem flange at an outer edge of the outer panel with a plasma polymer direct spray to cover the outer edge with a protective direct spray region. The method also includes overspraying the inner panel surface coated and exposed regions with a plasma polymer overspray to form a barrier coating.

In a third embodiment, a hem flange treatment method is disclosed. The method includes electrocoating a hem flange having inner and outer panels, each including inner surfaces and formed of different metals, to form inner panel surface coated and exposed regions. The method further includes spraying the hem flange at an outer edge of the outer panel with a plasma polymer direct spray to cover the outer edge with a protective direct spray region. The method also includes overspraying the inner panel surface coated and exposed regions with a plasma polymer overspray to form a barrier coating.

### BRIEF DESCRIPTION OF THE DRAWINGS

FIG. 1A illustratively depicts locations “a” to “h” on a vehicle door frame where cut edges may be exposed;

FIG. 1B illustratively depicts pillar locations “o” to “r” on a vehicle where cut edges may also be exposed;

FIG. 1C illustratively depicts a perspective view of a door frame portion having a cut egde;

FIG. 1D illustratively depicts an enlarged, fragmented view of the cut edge referenced in FIG. 1C;

FIG. 2 illustratively depicts a schematic view of a portion of a hem flange where a Faraday cage structure may be utlized;

FIG. 3A depicts a schematic view of a galvanic element formed between steel and zinc;

FIG. 3B depicts a schematic view of a galvanic element where zinc goes into solution and protects uncoated steel;

FIG. 4 depicts a flowchart showing the steps of a method for applying a surface coating in accordance with an embodiment;

FIGS. 5A to 5D depict images of cut edge of a control compared to the cut edges that received 1, 2 and 3 coats of plasma polymerized HMDSO (hexamethyldisiloxane), respectively;

FIGS. 6A to 6D depict images of the sides of a control in comparison to samples received 1, 2 or 3 coats of plasma polymerized HMDSO, respectively; and

FIG. 7 depicts a step of applying a polymer layer using atmospheric pressure air plasma via the use a plasma gun.

### DETAILED DESCRIPTION

Reference will now be made in detail to compositions, embodiments, and methods of the present invention known to the inventors. However, it should be understood that disclosed embodiments are merely exemplary of the present invention which may be embodied in various and alternative forms. Therefore, specific details disclosed herein are not to be interpreted as limiting, rather merely as representative bases for teaching one skilled in the art to variously employ the present invention.

Except where expressly indicated, all numerical quantities in this description indicating amounts of material or conditions of reaction and/or use are to be understood as modified by the word “about” in describing the broadest scope of the present invention.

The description of a group or class of materials as suitable for a given purpose in connection with one or more embodiments of the present invention implies that mixtures of any two or more of the members of the group or class are suitable. Description of constituents in chemical terms refers to the constituents at the time of addition to any combination specified in the description, and does not necessarily preclude chemical interactions among constituents of the mixture once mixed. The first definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

One of the problems associated with a cut edge and/or a hemmed flange is that sprayed paint loses energy upon contacting the areas where the cut edge or the hemmed flange is located. In these areas, due to geometry constraints, a spray coating may not be applicable, while an electro-coat is particularly designed to go into these tight regions where a normal spray coating could not penetrate. Even so, an electro-coat cannot penetrate an area where a Faraday cage exists. One may operate the paint spraying into the Faraday cage, yet one may not be able to ensure requisite adhesion of the paint.

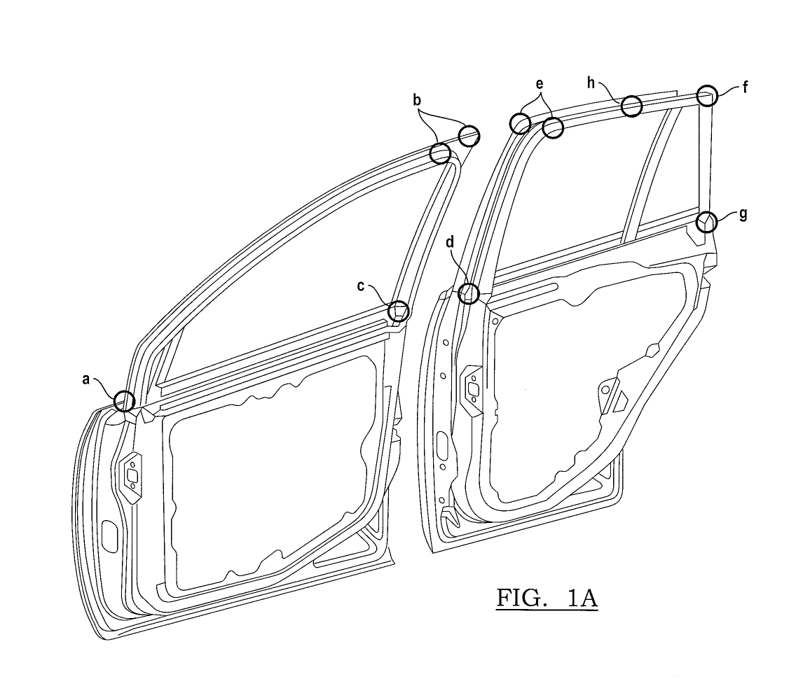

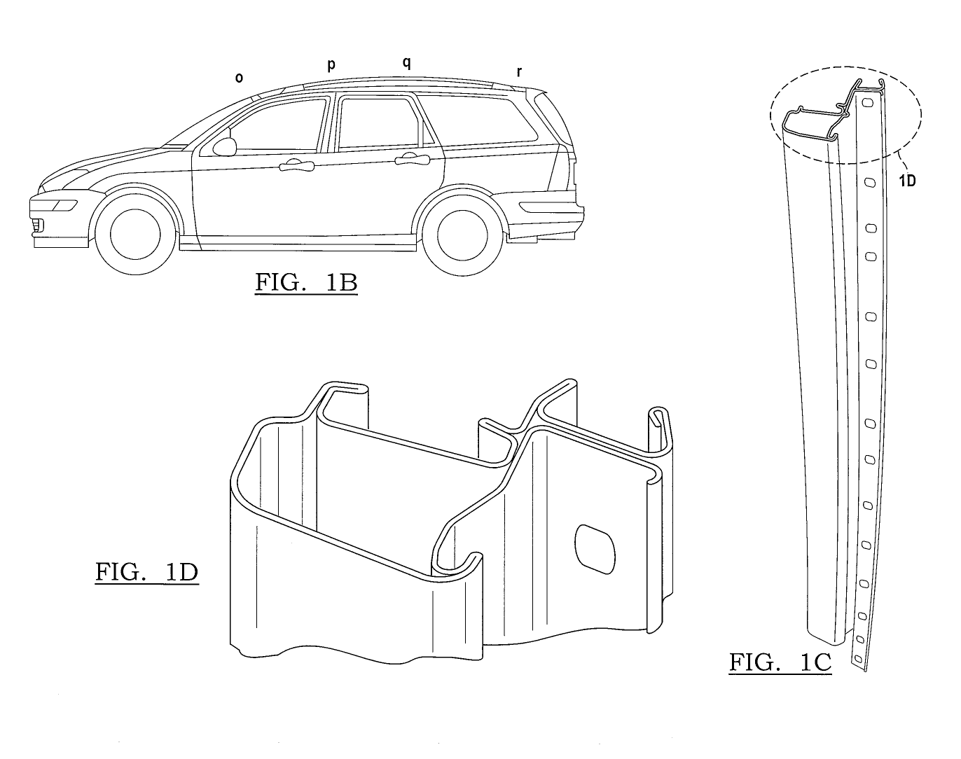

The term “cut edge” may refer to a surface of an article cut by a knife or other cutting tool. The cut edges may exist as the cut edges of a door seal guide as well as painted areas of the door frame welds. In the case of a door frame, cut edges may be located at positions “a” to “h” identified in FIG. 1A, and/or at junctions in the pillars “o” to “r” identified in FIG. 1B, wherein the pillars are those vertical or near vertical supports of a vehicle.

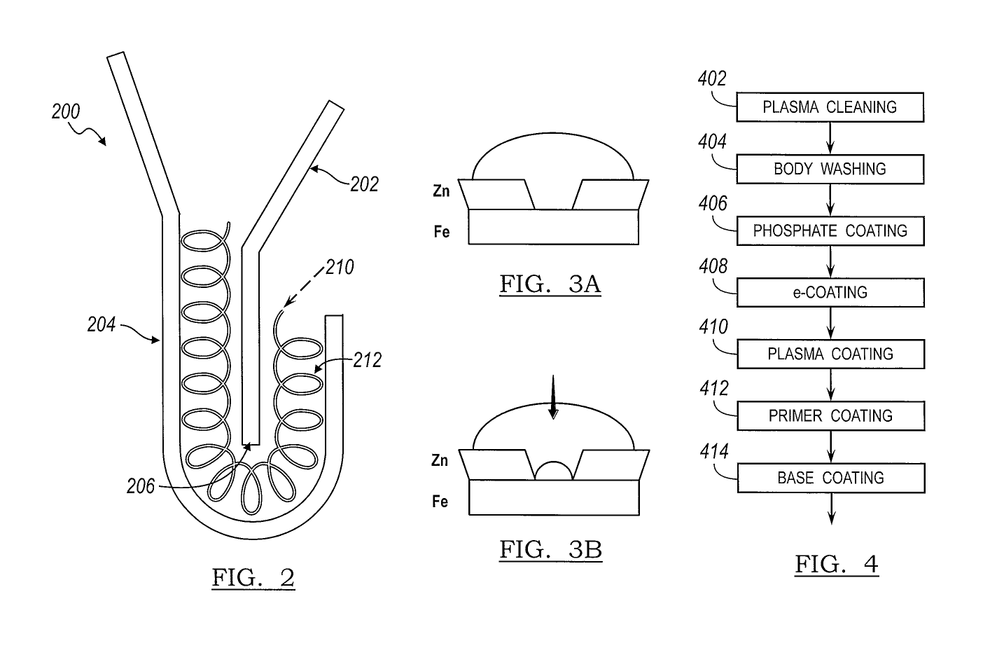

FIG. 2 illustratively depicts a portion of a hem flange 200 which, like those cut edges referenced in FIGS. 1A and 1B, is presented with certain geometry constraints, and hence substantial inaccessibility for an incoming coating intended for corrosion protection. As indicated in FIG. 2, the hem flange 200 includes an inner panel 202 received within an outer panel 204 with a cut edge 206 being exposed. Any corrosion initiating from the cut edge 206 may propagate to other areas of the inner panel 202 and even certain parts of the outer panel 204. If uncontrolled, the corrosion may develop over time to cause rusty appearances, structural damages and depreciation in value.

Referring back to FIG. 2, the cut edge 206 of the inner panel 202 is so positioned within the outer panel 204 that a Faraday structure has been created in effect. A Faraday cage is generally characterized in including an enclosure formed by conducting material such as a metallic material or by a mesh of such material. Such an enclosure blocks external static and non-static electric fields. As will be detailed herein elsewhere, the present invention in one or more embodiments reflects the discovery that the geometry constraints such as the creation of a Faraday structure in a hem flange reduces or prevents desirable reception of a corrosion-preventing coating such as an electro-coat within the hem flange. The present invention in one or more embodiments advantageously employs the use of polymerized coating material such as polymerized HMDSO, whose entry into the geometry-challenged areas such as a cut edge and/or a hem flange can be effectively driven by atmospheric pressure air plasma.

As stated herein above, corrosion on cut edges and/or hem flanges may be due to insufficient coverage of corrosion protection. The cut edge may also be particularly identified in relation to a door frame having an iron substrate with a galvanized (zinc) coating. Once the sacrificial coating is used up the iron starts to corrode, which is the obvious red rust. FIGS. 3A and 3B together depict corrosion associated with Zn dissolution. FIG. 3A shows a galvanic element formed between steel and zinc. FIG. 3B shows that zinc goes into solution and protects the uncoated steel. Zinc coating provides a continuous metallic barrier that may reduce contact of steel by moisture. However, since zinc gradually erodes due to its degradation in the presence of water and atmospheric pollutants in open air applications, barrier life may be proportional to coating thickness. In this connection, the barrier life may thus be limited due to the limit on the zinc coating thickness.

Cut edge quality may also be referred to burr quality. A burr is a raised edge or small pieces of material remaining attached to a work-piece after a modification process. It is usually an unwanted piece of material and when removed with a deburring tool in a process called ‘deburring’. Burrs are most commonly created after machining operations, such as grinding, drilling, milling, engraving or turning. Deburring may account for a significant portion of manufacturing costs.

FIG. 4 illustrates a non-limiting example of a method of applying the surface coating. Plasma treatment can be implemented in instances without unnecessary disruption of an existing painting system arrangement. At step 402, a plasma treatment (without the coating material) is applied to the cutting edge and its vicinity as necessary to remove oil deposits and other forms of contaminants including dirt. At step 404, the vehicle undergoes a body wash. At step 406, a phosphate coating is applied to the washed vehicle from step 402. At step 408, an electro-coat is applied to the phosphate coated vehicle from step 404. At step 410, a plasma coating is applied to the electro-coat treated vehicle. In comparison to the plasma treatment referenced in step 402, the plasma coating at step 410 includes the use of a coating material with polymerized HMDSO being a non-limiting example thereof. At step 412, a primer coating is applied to the plasma treated vehicle from step 410. At step 414, a base coat is applied to the vehicle from step 412.

The implementation of step 402 is advantageous because a potential cause of the cut edge corrosion lies in contamination accumulated on the cut edge, including oil deposits, prior to surface coating. Oil deposits may result from using of oil to reduce corrosions during transportation of parts. The cut edges, after iron casting, are often transported from the point of manufacture to a paint shop where the surface coatings are applied. During the transport, contaminants such as dirt and oil may accumulate on and around the surfaces of the cut edges upon which a surface coating is to be subsequently applied. In addition, subsequent cleaning may not be sufficient, wherein contamination of oil crust and metal chips may remain and hence impede subsequent painting efficiency. Soap may be used in an effort to cut down the oil deposits after use. However, soap itself can be problematic as a corrosion accelerator. In this connection, accumulated contaminants, if not sufficiently removed, will impede the coating performance and adhesion efficiency of the subsequently applied surface coating.

Adding a clear lacquer in an effort to reduce corrosion may not be effective as well, because the material is transparent and therefore is hard to see for the operator. Plasma cleaning followed by plasma coating has the potential to be better because this surface modification is applied with the plasma high energy that may allow for better adhesion to the substrate. The plasma coating is both a barrier coating and a surface modification. With surface modification the coating bonds chemically to the substrate. A barrier coating covers a substrate, but does not necessarily chemically bond to it. A paint layer is a barrier coating. The plasma coating would not necessarily be a conversion coating, since the substrate does not participate in its formation.

Implementing a plasma coating layer at step 410 following the electro-coat layer at step 408 is advantageous because the step of electro-coat may be as effective due to constraints in part geometry. In this connection, a polymer layer deposited by the atmospheric pressure air plasma is applied as a barrier coating such that exposed or hidden metal areas and cut edges may be protected from the environment. A particular example of the polymer layer includes plasma polymerized HMDSO.

In an alternative embodiment, the HMDSO plasma polymerized siloxane coating can be used as a barrier coating on one metal to insulate from a second and different metal when joining mixed metal structures. This will help prevent galvanic corrosion that can occur when mixed metals, e.g. aluminum and steel, are allowed to contact.

The atmospheric pressure air plasma may be applied via any suitable methods. By way of example, an exemplary air plasma treatment method is illustratively detailed in the U.S. Pat. No. 7, 744,984, entitled “method of treating substrates for bonding”, the content of which is incorporated herein in its entirety by reference.

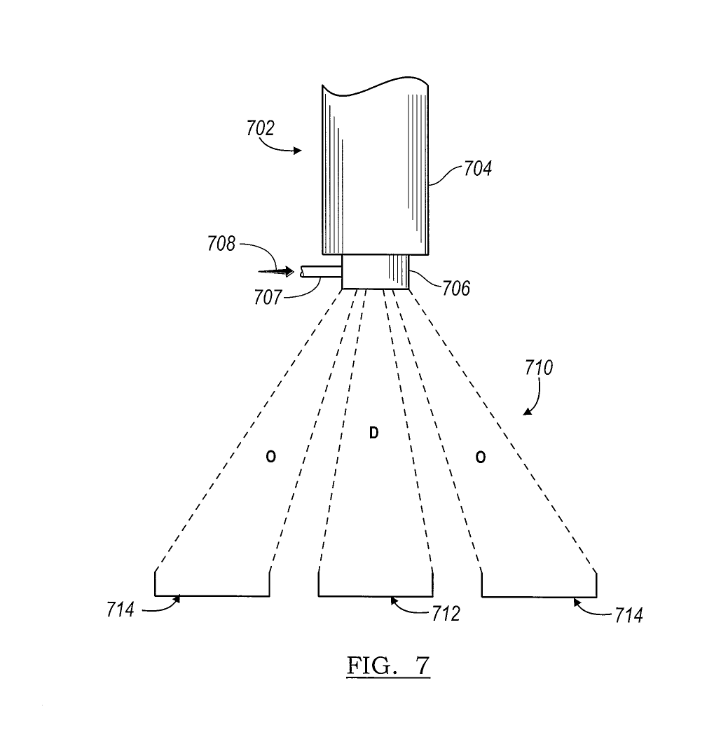

The step of applying a polymer layer using atmospheric pressure air plasma may be carried out via the use of a plasma gun 702 illustratively shown in FIG. 7. The plasma gun includes an outlet 706; introducing at least one pre-polymer molecule 708 into the outlet 706 of the plasma gun 702 to form a number of fragments of the pre-polymer molecule as a plasma output 710 including a direct-spray component 712 and an over-spray component 714. The plasma gun is optionally operated at atmospheric pressure.

The pre-polymer molecule may be introduced into the outlet 706 via a pipe 707. The pipe 707 may be attached to or built integral to the outlet 706. It is appreciated that the pipe 707 should be made of a material or be maintained in a condition that is compatible with the temperature of the pre-polymer molecule 708 to be introduced. By way of example, the pipe 707 should be heated and the material of the pipe 707 should sustain a particularly elevated temperature, in the event when the pre-polymer molecule 708 is introduced in a gas phase, such as unnecessary condensation may be effectively reduced or eliminated.

In addition, the plasma output 710 may be separated from each other to adjust the carbon content in the coating layer as deposited. For instance, as depicted in FIG. 7, the plasma output 710 may be separated into a direct-spray component 712 and an over-spray component 714 from each other to respectively obtain an isolated directed-spray component (such as region “D”) and an isolated over-spray component (such as region “O”). At least a portion of the isolated direct-spray component and at least a portion of the isolated over-spray component may be deposited.

The pre-polymer molecule 708 may be introduced in the form of a powder, a particle, a liquid, a gas, or any combinations thereof.

Suitable pre-polymer molecule 708 illustratively includes linear siloxanes; cyclical siloxanes; methylacrylsilane compounds; styryl functional silane compounds; alkoxyl silane compounds; acyloxy silane compounds; amino substituted silane compounds; hexamethyldisiloxane; tetraethoxysilane; octamethyltrisiloxane; hexamethylcyclotrisiloxane; octamethyl cyclotetrasiloxane; tetramethylsilane; vinylmethylsilane; vinyl triethoxysilane; vinyltris(methoxyethoxy) silane; aminopropyltriethoxysilane; methacryloxypropyltrimethoxysilane; glycidoxypropyltrimethoxysilane; hexamethyldisilazane with silicon, hydrogen, carbon, oxygen, or nitrogen atoms bonded between the molecular planes; organosilane halide compounds; organogermane halide compounds; organotin halide compounds; di[bis(trimethylsilyl)methyl]germanium; di[bis(trimethyl silyl)amino]germanium; tetramethyltin; organometallic compounds based on aluminum or titanium; or combinations thereof. Candidate prepolymers do not need to be liquids, and may include compounds that are solid but easily vaporized. They may also include gases that are compressed in gas cylinders, or are liquefied cryogenically, or are vaporized in a controlled manner by increasing their temperature.

The polymer layer formed from the pre-polymer molecules 708 via polymerization may include a silicon atomic percentage of 5 to 50, 10 to 40, or 15 to 35 atomic weight percent.

The polymer layer formed from the pre-polymer molecules 708 via polymerization may include an oxygen-to-silicon ratio of 1.0 to 4.0, 1.5 to 3.0, or 2.0 to 2.3.

Extent of energy imparted during a plasma depositing process is a function of several factors including beam speed and nozzle distance. Generally, higher the beam speed, the greater the nozzle distance, the lower the energy imparted. In certain particular embodiments wherein a lower energy output is desired, the beam speed is illustratively in the range of 200 to 800 millimeters per second and more particularly of 300-600 millimeters per second; the nozzle distance is illustratively in the range of 15 to 60 millimeters and more particularly of 20 to 30 millimeters; and a power level is in the range of 40 to 70% (percent) PCT (plasma pulse width). In certain other particular embodiments wherein a higher energy output is desired, the beam speed is illustratively in the range of 0.5 to 200 millimeters per second and more particularly of 25 to 100 millimeters per second; the nozzle distance is illustratively in the range of 0.5 to 15 millimeters and more particularly of 4 to 10 millimeters; and a power level is in the range of 70 to 100% PCT (plasma pulse width).

Coatings with various carbon and oxygen contents may be obtained through the adjustment of the output ratio between the direct-spray and the over-spray. By way of example, a coating having 40 atomic percentage of carbon atoms may be obtained when half of the coating in volume comes from the direct-spray having an average of 20 atomic percentage of carbon atoms and the other half of the coating in volume comes from the over-spray having an average of 60 atomic percentage of carbon atoms. An off-exit mixer may be attached to the plasma outlet to ensure a thorough mixing of the relative portions of the direct-spray and the over-spray. As such, a coating may be obtained of any controlled carbon content between the carbon content of the direct-spray and the over-spray.

The spray pattern and the energy output of a plasma deposition may be adjusted such that an overspray portion of the plasma may reach over to a location that is not otherwise accessible to a regular paint spray. A mass or flow divider may be used to separate the extent and/or the direction of the over-spray portion and the direct-spray portion such that the extent of the accessibility may be further adjustable.

The flexibility and versatility in controlling the coating chemistry is further bolstered when the carbon content of the direct-spray or the over-spray is itself adjustable. The greater is the differential carbon content between the direct-spray and the over-spray, the more controllably versatile the resulting coating chemistry becomes.

The extent and composition of the plasma output may further be modified by modulating the level of plasma energy imparted during a plasma depositing process. As a result, the amount of the direct-spray component or the amount of the over-spray component may be altered accordingly. This base level output modification, when coupled with various shielding and mixing described herein, creates substantial versatility in controlling the chemistry of a plasma coating resulting therefrom.

The electro-coat, primer coat, and basecoat may be used with any suitable chemistry and be applied in any suitable manner. Non-limiting examples of chemistries that can be utilized include acrylic/melamine, carbamate, urethane, epoxy-acid and polyester. Useful crosslinkable resins include acrylic polymers, polyesters, alkyds, polyurethanes, polyamides, polyethers and copolymers and mixtures thereof. These resins can be self-crosslinking or crosslinked by reaction with suitable crosslinking materials included in the coating composition.

Suitable acrylic polymers include copolymers of one or more alkyl esters of acrylic acid or methacrylic acid, optionally together with one or more other polymerizable ethylenically unsaturated monomers.

Useful alkyl esters of acrylic acid or methacrylic acid include aliphatic alkyl esters containing from 1 to 30, and preferably 4 to 18 carbon atoms in the alkyl group. Non-limiting examples include methyl methacrylate, ethyl methacrylate, butyl methacrylate, ethyl acrylate, butyl acrylate, and 2-ethyl hexyl acrylate.

Suitable other copolymerizable ethylenically unsaturated monomers include vinyl aromatic compounds such as styrene and vinyl toluene; nitriles such as acrylonitrile and methacrylonitrile; vinyl and vinylidene halides such as vinyl chloride and vinylidene fluoride; and vinyl esters such as vinyl acetate.

Alkyd resins or polyester polymers can be prepared in a known manner by condensation of polyhydric alcohols and polycarboxylic acids. Suitable polyhydric alcohols include ethylene glycol, propylene glycol, butylene glycol, 1,6-hexylene glycol, neopentyl glycol, diethylene glycol, glycerol, trimethylol propane and pentaerythritol.

Suitable polycarboxylic acids include succinic acid, adipic acid, azelaic acid, sebacic acid, maleic acid, fumaric acid, phthalic acid, tetrahydrophthalic acid, hexahydrophthalic acid and trimellitic acid. Besides the polycarboxylic acids mentioned above, functional equivalents of the acids such as anhydrides where they exist or lower alkyl esters of the acids such as methyl esters can be used.

Useful polyurethanes include polymeric polyols which are prepared by reacting polyester polyols or acrylic polyols with a polyisocyanate.

Having generally described several embodiments of this invention, a further understanding can be obtained by reference to certain specific examples which are provided herein for purposes of illustration only and are not intended to be limiting unless otherwise specified.

### EXAMPLE

Cut edges of a galvanized steel door frame depicted in FIGS. 4A and 4B are coated with plasma polymerized HMDSO by means of an Openair®PlasmaPlus® air plasma system manufactured by Plasmatreat, NA. The system injects HMDSO into an air plasma stream at the exit nozzle of an atmospheric pressure air plasma gun where it reacts to form a polymerized coating on the substrate upon contact. The plasma head is traversed over the edge of a piece cut from the door frame at a speed of 100 mm/s and distance of 6 mm. A set of door frame edges are coated 1, 2 and 3 times with the plasma polymerized HMDSO. The door frame pieces are then submerged in a 4% aqueous sodium chloride solution for 7 days to accelerate corrosion.

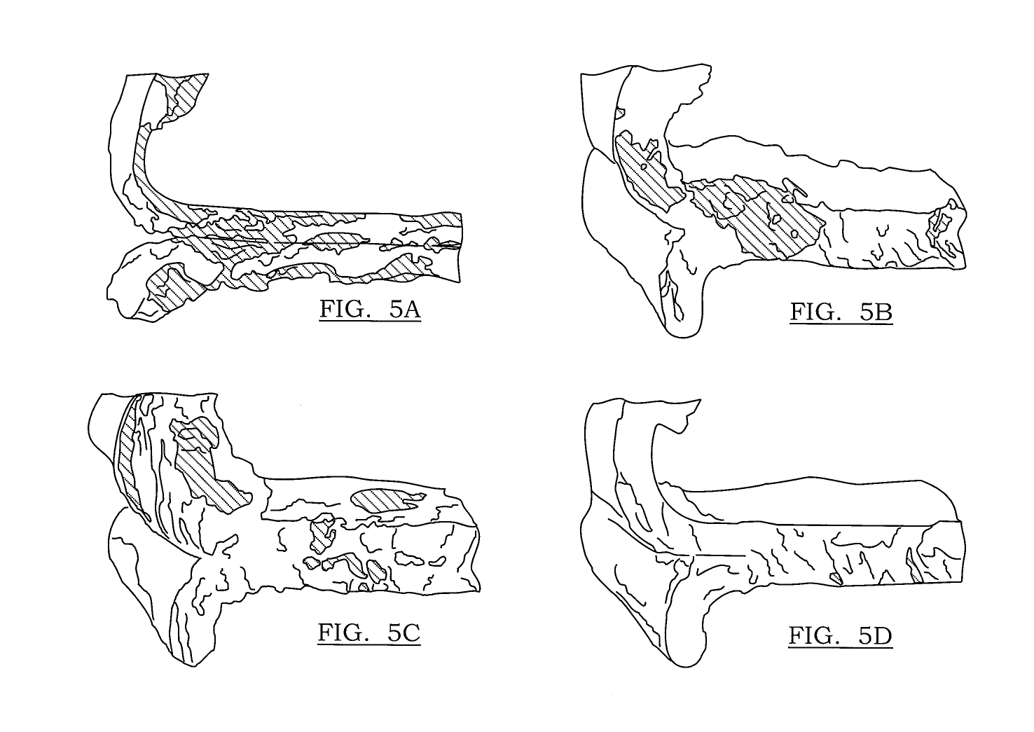

Images of the cut edge of a control compared to the cut edges that have received 1, 2 and 3 coats of plasma polymerized HMDSO are shown in FIGS. 5A to 5D. Iron oxide corrosion is quite evident on the control sample, represented in FIG. 5A with relatively heavier shading. The amount of corrosion is observed to be reduced on the sample that received 1 coat of plasma polymerized HMDSO depicted in FIG. 5B, reduced further on the sample that received 2 coats depicted in FIG. 5C, and is mostly eliminated on the sample that received 3 coats depicted in FIG. 5D as having the least amount of shading.

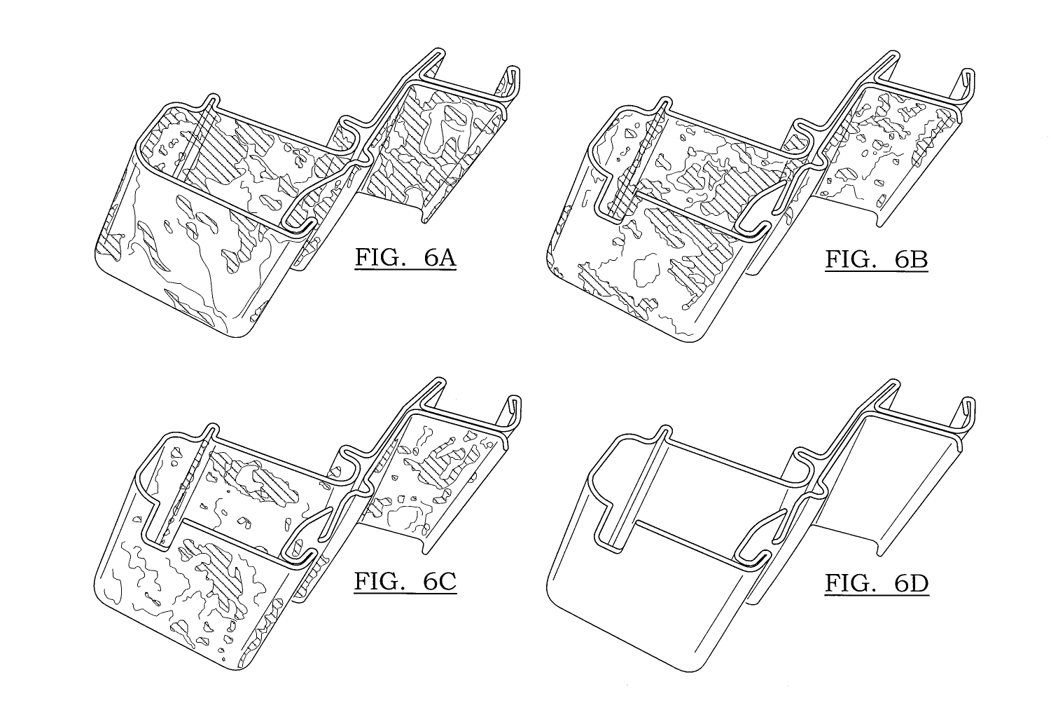

Surprisingly, it is noticed that, besides the cut edge that received direct impingement of the plasma polymerized HMDSO coating, the entire sample is observed to have been protected from corrosion induced from the salt bath. This is evident from the images shown in FIG. 6A to 6D, where the sides of the control and 1-coat samples show high amounts of red iron oxide rust represented by relatively heavier shading, the sides of the sample with 2 coats show much less rust, and almost no rust is evident on the sides of the sample that received 3 coats of plasma polymerized HMDSO. These results demonstrate that the polymerized HMDSO coating is effective not only where there is direct impingement of the air plasma, but also along the body of the part where activated chemical species in an overspray continue to react, polymerize, and form a protective coating. Thus as a reference, when deposited on a silicon wafer under the deposition parameters utilized here and rastered at a track pitch (distance between rasters) of 1 mm, one application of air plasma polymerized HMDSO results in a siloxane coating of atomic composition 10.6% C, 27.4% Si and 62.0% O at a thickness of 40 nanometers (nm) at the point of direct impingement by the air plasma stream, and an atomic composition of 18.2% C, 25.1% Si and 56.7% O at a thickness of 20 nm at a distance 40 mm away from the point of direct impingement by the air plasma stream.

The results of this experiment reveal that the siloxane coating deposited by plasma polymerized HMDSO is effective at abating metal corrosion both at the region of direct impingement by the air plasma stream, as well as in areas adjacent to the region of direct impingement where an overspray forms a protective coating. This overspray can be utilized to coat hidden areas that are not accessible for a protective coating by direct line of sight.

An example of such might be the hem flange 200 of open design with limited access as shown in FIG. 2 where a Faraday cage is formed that may reject deposition from an electro-coat bath. In this case the activated chemical species in the overspray mist formed from a plasma polymerized HMDSO coating could travel through the hem from the point of a direct spray portion 210 to the point of an overspray portion 212, contacting and forming a protective corrosion-resistant coating on areas (such as the cut end of the inner hem panel) where contact is not possible by direct line of sight.

While the best mode for carrying out the invention has been described in detail, those familiar with the art to which this invention relates will recognize various alternative designs and embodiments for practicing the invention as defined by the following claims.

What is claimed:

1. A method comprising:
air plasma direct spraying a hem flange at an outer edge of an outer panel thereof with a plasma polymer direct spray to cover the outer edge with a protective direct spray region; and
air plasma overspraying a cut edge of an inner panel of the hem flange with a plasma polymer overspray to form a protective overspray region that covers the inner cut edge.

2. The method of claim 1, wherein the plasma polymer overspray exits the hem flange at an inner opening between the outer and inner panels.

3. The method of claim 1, further comprising directly applying a phosphate coating to the surfaces of the inner panel and the cut edge prior to the air plasma direct spraying and overspraying steps to form an inner panel phosphate coated surface.

4. The method of claim 3, further comprising directly applying an electrocoat to the inner panel phosphate coated surface to form inner panel coated regions and inner panel exposed regions.

5. The method of claim 4, wherein the air plasma direct spraying and overspraying steps form a barrier coating on the inner panel coated and exposed regions.

6. The method of claim 4, wherein the inner panel exposed regions include exposed regions on the cut edge.

7. The method of claim 1, wherein the plasma polymer direct spray includes polymerized HMDSO.

8. A method comprising:
electrocoating a hem flange having inner and outer panels, each including inner surfaces, to form inner panel surface coated and exposed regions;
spraying the hem flange at an outer edge of the outer panel with a plasma polymer direct spray to cover the outer edge with a protective direct spray region; and
overspraying the inner panel surface coated and exposed regions with a plasma polymer overspray to form a barrier coating.

9. The method of claim 8, wherein the inner panel surface exposed regions include a cut edge of the inner panel.

10. The method of claim 8, wherein the plasma polymer direct spray includes polymerized HMDSO.

11. The method of claim 8, further comprising applying a primer coating to the barrier coating.

12. The method of claim 11, further comprising applying a base coat to the primer coating.

13. The method of claim 8, wherein the spraying step is an air plasma spraying step.

14. The method of claim 8, wherein the overspraying step is an air plasma spraying step.

15. A method comprising:
electrocoating a hem flange having inner and outer panels, each including inner surfaces and formed of different metals, to form inner panel surface coated and exposed regions;
spraying the hem flange at an outer edge of the outer panel with a plasma polymer direct spray to cover the outer edge with a protective direct spray region; and
overspraying the inner panel surface coated and exposed regions with a plasma polymer overspray to form a barrier coating.

16. The method of claim 15, wherein the inner panel surface exposed regions include a cut edge of the inner panel.

17. The method of claim 15, wherein the plasma polymer direct spray includes polymerized HMDSO.

18. The method of claim 15, further comprising applying a primer coating to the barrier coating.

19. The method of claim 18, further comprising applying a base coat to the primer coating.

20. The method of claim 15, wherein the spraying step is an air plasma spraying step.
